(19) United States
(12) Patent Application Publication
(10) Pub. No.: US 2016/0268153 A1
(43) Pub. Date: Sep. 15, 2016

(54) SUBSTRATE FLOATING APPARATUS, SUBSTRATE TRANSFER APPRATUS, AND SUBSTRATE TRANSPORT APPARATUS

(71) Applicant: MURATA MACHINERY, LTD., Kyoto-shi, Kyoto (JP)

(72) Inventor: Hirotaka WADA, Inuyama-shi (JP)

(73) Assignee: Murata Machinery, Ltd, Kyoto-shi, Kyoto (JP)

(21) Appl. No.: 15/035,844

(22) PCT Filed: Oct. 6, 2014
(86) PCT No.: PCT/JP2014/005077

§ 371 Date: May 11, 2016

(30) Foreign Application Priority Data
Nov. 13, 2013 (JP) 2013-235246

(51) Int. Cl. H01L 21/677; B65G 51/03; B65G 49/06

(52) U.S. Cl. CPC H01L 21/67784; B65G 49/065; B65G 51/03

(57) ABSTRACT

Provided are a substrate floating apparatus, substrate transfer apparatus, and substrate transport apparatus that achieve energy savings, the saving of space, maintenance-free operation, low costs and an increase in controllability of airflow. The substrate floating apparatus according to the present invention floats a substrate above a placing surface by jetting air from a plurality of jetting ports, and includes: a plate having a surface that is the placing surface and including the plurality of jetting ports penetrating the plate in a thickness direction and spaced apart from one another at a given interval; a plurality of air blowers that blow air toward the plurality of jetting ports from a rear side of the plate by vibrating a diaphragm; and a controller that controls driving of the plurality of air blowers.

### TECHNICAL FIELD

The present invention relates to a substrate floating apparatus, substrate transfer apparatus, and substrate transport apparatus for floating and transporting an object to be transported, such as a substrate, by blowing air.

### BACKGROUND ART

A conventional transport apparatus is known that floats an object to be transported by generating high-pressure air using a compressor, storing the high-pressure air in a tank, and blowing the high-pressure air stored in the tank from a plurality of nozzles toward the bottom surface of the object to be transported (see for example Patent Literature (PTL) 1).

### CITATION LIST

### Patent Literature

[PTL 1] Japanese Unexamined Patent Application Publication No. 2005-75497.

### SUMMARY OF INVENTION

### Technical Problem

With the above-described conventional technique, however, when an apparatus that generates high-pressure air such as a compressor, small fan, or blower (hereinafter such an apparatus is referred to as a high-pressure air generator) is used, a large amount of power is required to generate the high-pressure air.

Moreover, in this case, since the high-pressure air generator includes a rotating mechanism or sliding mechanism, there is a problem that the friction from the mechanism generates dust. For this reason, with this conventional technique, a filter is provided to remove dust. However, since the filter clogs after removing a predetermined amount of dust, regular maintenance is required in order to maintain the amount of high-pressure air pumped in. In other words, with this conventional technique, if maintenance is not regularly performed, performance cannot be maintained.

Moreover, since high-pressure air is blown from the transportation path along which the object to be transported travels, plumbing equipment is required to feed the high-pressure air to the transportation path. This increases the cubic volume of the transport apparatus, which in turn makes it necessary to secure a space of sufficient size to install the transport device. Installation of the plumbing equipment is also costly.

Moreover, when the transport apparatus is applied in a clean room, installation of equipment for rectifying the high-pressure air such as a chamber in the plumbing equipment is further required, which further increases the cubic volume of the transport apparatus.

Furthermore, when the plumbing is equipped with a filter or chamber, for example, control of the flow of the high-pressure air (the responsiveness of the flow) worsens and efficient operation cannot be carried out.

Thus, the present invention has been made in view of the above problems, and has an object to provide a substrate floating apparatus, substrate transfer apparatus, and substrate transport apparatus that achieve energy savings, the saving of space, maintenance-free operation, low costs, and an increase in controllability of airflow.

### Solution to Problem

In order to achieve the above object, a substrate floating apparatus according to one aspect of the present invention floats a substrate above a placing surface by jetting air from a plurality of jetting ports, and includes: a plate having a surface that is the placing surface and including the plurality of jetting ports, the plurality of jetting ports penetrating the plate in a thickness direction of the plate and spaced apart from one another at a given interval, a plurality of air blowers that blow air toward the plurality of jetting ports from a rear side of the plate by vibrating a diaphragm; and a controller that controls driving of the plurality of air blowers.

According to this configuration, the plurality of air blowers can blow air by vibrating the diaphragm. In other words, since the air blower, which is the source of generation of the flow of air blown from the plurality of jetting ports, does not include a rotating mechanism or a sliding mechanism, generation of dust can be suppressed. Therefore, a filter for removing dust resulting from friction generated by such a mechanism need not be provided. This eliminates the need for regular maintenance and increases user convenience.

Moreover, since the plurality of air blowers are disposed directly on the rear sides of the plurality of jetting ports, installation of plumbing is not required. For this reason, a space for installing plumbing equipment need not be secured and the substrate floating apparatus itself can be compact in cubic volume. Moreover, costs incurred from installing plumbing equipment (including a chamber) can be cut. Furthermore, since the plurality of air blowers can directly send air to the plurality of jetting ports, air jetted from the plurality of jetting ports can be controlled by controlling the plurality of air blowers, and controllability of the flow of air can be increased.

For example, the plurality of air blowers may be provided in one-to-one correspondence with the plurality of jetting ports.

According to this configuration, controllability of the air jetted from each of the plurality of jetting ports can be increased.

For example, the controller may control driving of the plurality of air blowers individually.

According to this configuration, since each of the plurality of air blowers is individually controlled, it is possible, for example, to control only the plurality of air blowers directly under the substrate among the plurality of air blowers. In this way, since the number of air blowers used to float the substrate can be controlled, the amount of power consumed by the plurality of air blowers can be kept to the minimum amount required.

For example, each of the plurality of air blowers may include: the diaphragm; a housing that includes an inlet for drawing air into an interior space, and an outlet that communicates at least one of the plurality of jetting ports with the interior space, the diaphragm being disposed in the interior space of the housing; and a drive source that vibrates the diaphragm. The drive source may draw air into the interior space of the housing through the inlet and expel air from the interior space through the outlet by vibrating the diaphragm.

According to this configuration, since each of the plurality of air blowers has a configuration that draws air into the interior space of the housing through the inlet and expels air from the interior space through the outlet as a result of the drive source vibrating the diaphragm, generation of mechanical friction is unlikely when driven. Consequently, even when the air blower is driven, dust can be kept from being generated.

For example, the drive source may be a piezoelectric element that vibrates when applied with voltage.

According to this configuration, vibration can be efficiently transmitted to the diaphragm by applying voltage to the drive source. Moreover, since diaphragm can be instantly vibrated when voltage is applied, the responsiveness of vibration of the diaphragm can be increased.

For example, each of the plurality of air blowers may be a blower without a check valve between the inlet and the outlet of the housing. Moreover, for example, each of the plurality of air blowers may be a piezoelectric pump that includes a check valve between the inlet and the outlet of the housing.

Moreover, for example, each of the plurality of air blowers may further include, at the inlet of the housing, a filter for removing dust.

According to this configuration, dust in the air outside the air blower can be prevented from being drawn in. This keeps the blowing efficiency of the air blower from decreasing due to dust.

A substrate transfer apparatus according to another aspect of the present invention is for placing and removing a substrate in and from a predetermined placement position, and includes: a plurality of arms that are elongated and plate-shaped and include a plurality of jetting ports penetrating the plurality of arms in a plate thickness direction and spaced apart from one another at a given interval; a plurality of air blowers that blow air toward the plurality of jetting ports from rear sides of the plurality of arms; and a controller that controls driving of the plurality of air blowers.

Moreover, a substrate transport apparatus according to another aspect of the present invention transports a substrate by floating the substrate from a surface of a transporting path by jetting air from a plurality of jetting ports formed in the transporting path, and includes: a plate having a surface that is the surface of the transporting path and including the plurality of jetting ports, the plurality of jetting ports penetrating the plate in a thickness direction of the plate and spaced apart from one another at a given interval; a plurality of air blowers that blow air toward the plurality of jetting ports from a rear side of the plate; and a controller that causes, among the plurality of air blowers, an air blower corresponding to a jetting port positioned below the substrate to blow air.

### Advantageous Effects of Invention

The substrate floating apparatus, substrate transfer apparatus, and substrate transport apparatus according to the present invention can achieve energy savings, the saving of space, maintenance-free operation, low costs, and an increase in controllability of airflow.

### BRIEF DESCRIPTION OF DRAWINGS

FIG. 1 illustrates a substrate transport apparatus which uses a substrate floating apparatus according to Embodiment 1.

FIG. 2 is an enlarged view of region P1 in (b) in FIG. 1.

FIG. 3 is an enlarged view of a region of a substrate floating apparatus according to Variation (1) corresponding to region P1 in (b) in FIG. 1.

FIG. 4 is an enlarged view of a region of a substrate floating apparatus according to Variation (3) corresponding to region P1 in (b) in FIG. 1.

FIG. 5 is a perspective external view of a substrate transfer apparatus according to Embodiment 2.

### DESCRIPTION OF EMBODIMENTS

Hereinafter, the substrate floating apparatus, substrate transfer apparatus, and substrate transport apparatus according to one aspect of the present invention will be described in detail with reference to the drawings.

It is to be noted that each of the embodiments described below shows a specific example of the present invention. The numerical values, shapes, materials, elements, the arrangement and connection of the elements, steps, the processing order of the steps etc. shown in the following embodiments are mere examples, and therefore do not limit the present invention. Moreover, among the elements in the following embodiments, those elements not recited in any one of the independent claims defining the most generic part of the inventive concept are described as arbitrary elements.

### Embodiment 1

The substrate transport apparatus according to Embodiment 1 transports substrates along a transporting path using a substrate floating apparatus that jets air from a plurality of jetting ports formed in the transporting path to float the substrate from a placing surface.

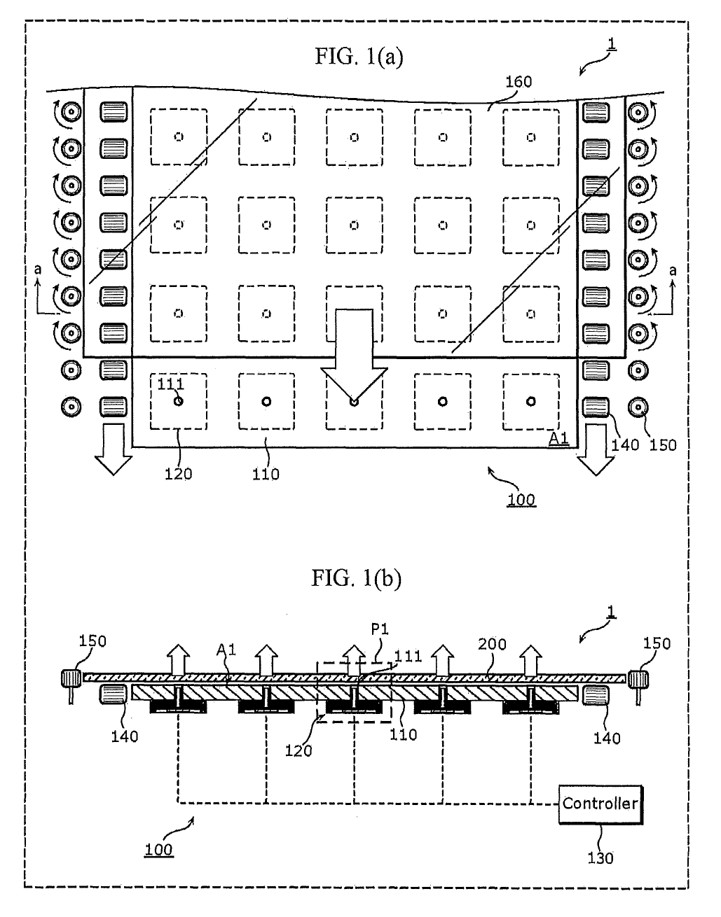

FIG. 1 illustrates the substrate transport apparatus which uses the substrate floating apparatus according to Embodiment 1. In FIG. 1, (a) is a plan view of the substrate transport apparatus 1 from above, and (b) is a cross sectional view taken along line a-a in (a).

The substrate transport apparatus 1 includes a substrate floating apparatus 100 as a frame, a transport roller 140, and a guide roller 150.

The substrate floating apparatus 100 includes a plate 110, a plurality of air blowers 120, and a controller 130.

The plate 110 has a surface A1 that is the placing surface for a substrate 160 and includes a plurality of jetting ports 111 penetrating the plate 110 in a thickness direction and spaced apart from one another at a given interval.

The plurality of air blowers 120 blow air toward the plurality of jetting ports 111 from a rear side of the plate 110 by vibrating a diaphragm. Moreover, the plurality of air blowers 120 are provided in one-to-one correspondence with the plurality of jetting ports 111 included in the plate 110.

The controller 130 controls driving of the plurality of air blowers 120. The controller 130, for example, controls driving of the plurality of air blowers 120 individually. In other words, the controller 130 may control each of the plurality of air blowers 120 individually.

FIG. 2 is an enlarged view of region P1 in (b) in FIG. 1. In other words, FIG. 2 is for illustrating the configuration of the air blower 120.

Each of the plurality of air blowers 120 includes a diaphragm 124, a housing 121, and a piezoelectric element 125 as a drive source.

The housing 121 includes an inlet 122 and an outlet 123. Moreover, the housing 121 defines an interior space S1 in which the diaphragm 124 and the piezoelectric element 125 are disposed. In other words, housing 121 contains therein the diaphragm 124. The inlet 122 is formed in the bottom of housing 121. The inlet 122 is an opening for drawing air into the interior space S1 from outside. The outlet 123 is formed on the top of housing 121. The outlet 123 is cylindrical in shape and blows the flow of air generated in the interior space S1 of housing 121 into one of the plurality of jetting ports 111 formed in the plate 110. In other words, the outlet 123 communicatively connects one of the plurality of jetting ports 111 with the interior space S1. Moreover, the outer circumferential surface of the cylindrical shape of the outlet 123 is in contact with the inner circumferential surface of the jetting port 111. Therefore, airflow generated from each of the plurality of air blowers 120 is efficiently jetted out from a corresponding one of the plurality of jetting ports 111.

When voltage is applied, the piezoelectric element 125 vibrates and causes the diaphragm 124 to vibrate. The piezoelectric element 125 vibrates the diaphragm 124 to draw air into the interior space S1 of the housing 121 through the inlet 122 and expel air from the interior space S1 through the outlet 123. The piezoelectric element 125 transmits vibrations to the diaphragm 124 by coming into surface contact with the diaphragm 124. Note that the diaphragm 124 is simply a film-like member, but the piezoelectric element 125 may include the functions of diaphragm 124. In other words, the diaphragm may be structured to be a piezoelectric element itself.

For example, a microblower manufactured by Murata Manufacturing Company, Ltd. may be used as the above-described air blower 120.

With the substrate floating apparatus 100 according to Embodiment 1, each of the plurality of air blowers 120 blow air by vibrating the diaphragm 124. In other words, since the air blower 120, which is the source of generation of the flow of air blown from each of the plurality of jetting ports 111, does not include a rotating mechanism or a sliding mechanism, generation of dust can be suppressed. Therefore, a filter for removing dust resulting from friction generated by such a mechanism need not be provided. This eliminates the need for regular maintenance and increases user convenience.

Moreover, since the plurality of air blowers 120 are disposed directly on the rear sides of the plurality of jetting ports 111, installation of plumbing is not required. For this reason, a space for installing plumbing equipment need not be secured and the substrate floating apparatus 100 itself can be compact in cubic volume. Moreover, costs incurred from installing plumbing equipment (including a chamber) can be cut. Furthermore, since the plurality of air blowers 120 can directly send air to the plurality of jetting ports 111, air jetted from the plurality of jetting ports 111 can be controlled by controlling the plurality of air blowers 120. In other words, controllability of the air jetted from the plurality of jetting ports 111 can be increased.

Moreover, with the substrate floating apparatus 100 according to Embodiment 1, since each of the plurality of air blowers 120 has a configuration that draws air into the interior space S1 of the housing 121 through the inlet 122 and expels air from the interior space S1 through the outlet 123 as a result of the piezoelectric element 125 vibrating the diaphragm 124, generation of mechanical friction is unlikely when driven. Consequently, even when the air blower 120 is driven, dust can be kept from being generated.

Moreover, with the substrate floating apparatus 100 according to Embodiment 1, since the plurality of air blowers 120 are provided in one-to-one correspondence with the plurality of jetting ports 111, controllability of the air jetted from each of the plurality of jetting ports 111 can be increased.

Moreover, with the substrate floating apparatus 100 according to Embodiment 1, since each of the plurality of air blowers 120 is individually controlled, it is possible, for example, to control only the plurality of air blowers 120 directly under the substrate among the plurality of air blowers 120. In this way, since the number of air blowers 120 used to float the substrate 160 can be controlled, the amount of power consumed by the plurality of air blowers 120 can be kept to the minimum amount required.

Moreover, with the substrate floating apparatus 100 according to Embodiment 1, since the piezoelectric element 125, which vibrates when applied with voltage, is used as the drive source, vibration can be efficiently transmitted to the diaphragm 124 by applying voltage to the piezoelectric element 125. Moreover, since the diaphragm 124 can be instantly vibrated when voltage is applied to the piezoelectric element 125, the responsiveness of vibration of the diaphragm 124 can be increased.

(Variations)

(1)

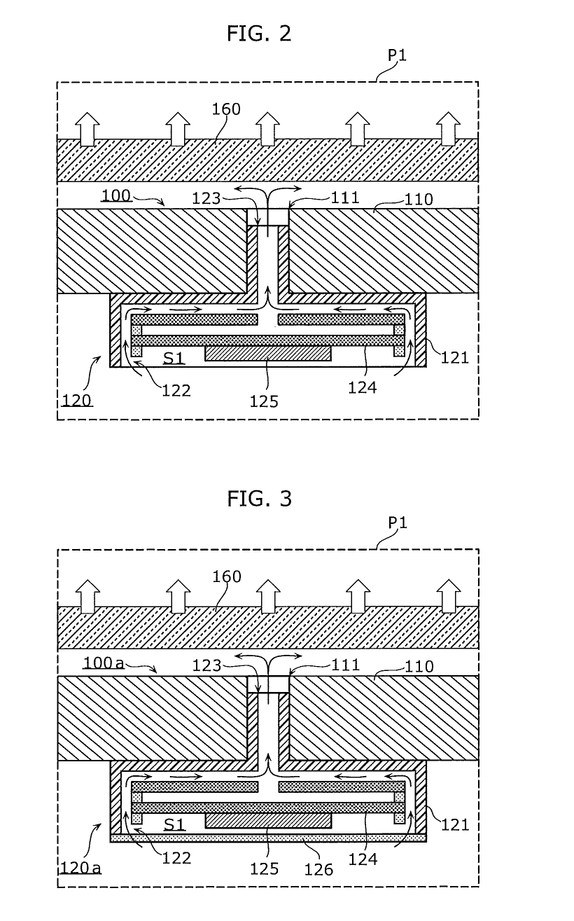

With the substrate floating apparatus 100 according to Embodiment 1, the inlet 122 of the housing 121 of the plurality of air blowers 120 is merely an opening, but this is only one example. For example, as illustrated in FIG. 3, a substrate floating apparatus 100a which employs an air blower 120a including a filter 126 disposed at the inlet 122 for removing dust is acceptable.

According to this configuration, even when dust is in the air outside each of the plurality of air blowers 120a, the dust can be kept from being drawn into the interior space S1 of the housing 121. Therefore, the blowing efficiency of the air blower 120a can be kept from decreasing due to dust.

(2)

With the substrate floating apparatus 100 according to Embodiment 1, the diaphragm 124 of each of the plurality of air blowers 120 is vibrated by the piezoelectric element 125, but this is only one example. For example, the diaphragm 124 may be vibrated by rotating a cam. Note that in this case, the plurality of air blowers generate dust from friction, but this configuration is still advantageous since plumbing equipment is not required for the substrate floating apparatus.

(3)

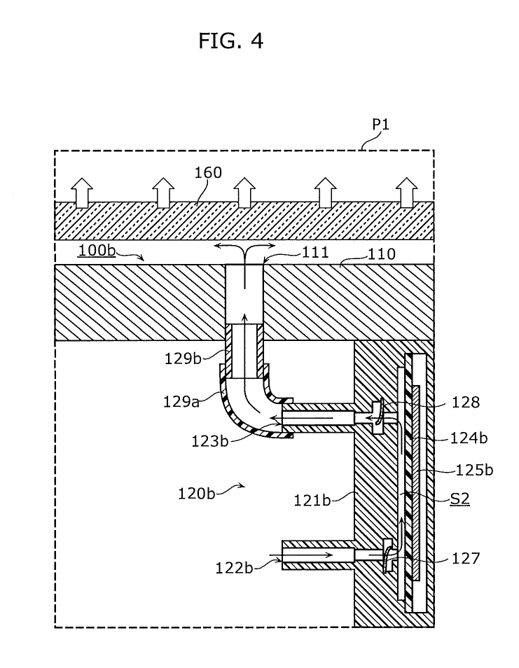

With the substrate floating apparatus 100 according to the above embodiment, each of the plurality of air blowers 120 is a microblower that does not include a check valve between the inlet 122 and the outlet 123 of the housing 121, but this is just one example. For example, as illustrated in FIG. 4, a substrate floating apparatus 100b that employs piezoelectric pumps as the plurality of air blowers 120 is acceptable.

The air blower 120b according to Variation (3) includes check valves 127 and 128 in addition to a diaphragm 124b, a housing 121b, and a piezoelectric element 125b as the drive source.

The housing 121b includes a cylindrical inlet 122b and outlet 123b. Moreover, the housing 121 defines an interior space S2 in which the diaphragm 124b and the piezoelectric element 125b are disposed. The inlet 122b and the outlet 123b are in communication with the interior space S2. The check valve 127 is disposed between the inlet 122b and the interior space S2 and is for preventing reverse flow of air drawn into interior space S2 toward inlet 122. Moreover, the check valve 128 is disposed between the outlet 123b and the interior space S2 and is for preventing reverse flow of air expelled from interior space S2 toward interior space S2. The outlet 123b of air blower 120b and the jetting port 111 formed in the plate 110 are connected together in a state in which they are in communication with one another via communicating members 129a and 129b.

Note that, for example, a piezo-micro pump manufactured by Takasago Electric, Inc. may be used as the above-described air blower 120b.

### Embodiment 2

The substrate transfer apparatus according to Embodiment 2 includes a plurality of jetting ports formed in an arm on which a substrate is placed, and the substrate is floated from the surface of the arm by jetting air from the plurality of jetting ports to transfer the substrate from the arm to a predetermined placement position.

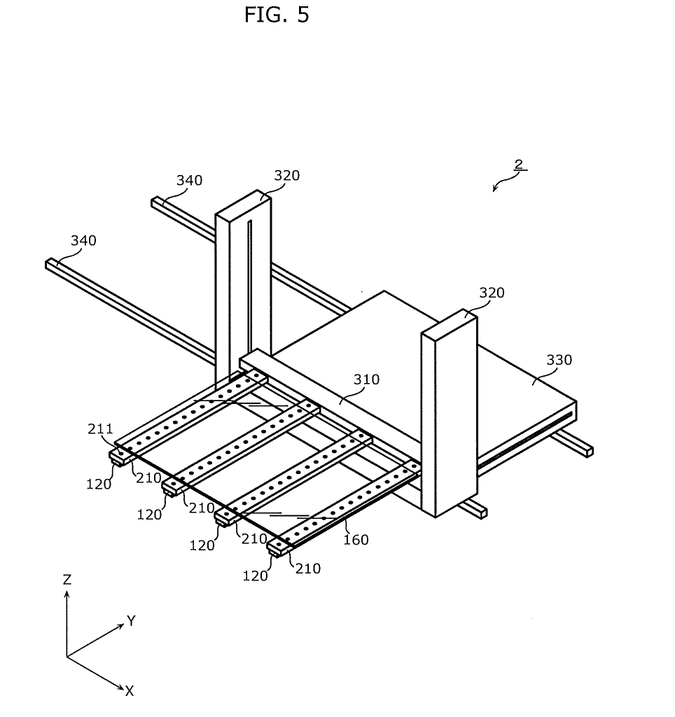

FIG. 5 is a perspective external view of the substrate transfer apparatus according to Embodiment 2.

The substrate transfer apparatus 2 includes at least a plurality of arms 210 and the plurality of air blowers 120. As illustrated in FIG. 5, the substrate transfer apparatus 2 according to Embodiment 2 further includes a support 310 that supports the plurality of arms 210 (four arms 210 in this embodiment), a first guide 320, a second guide 330, and a third guide 340.

Each of the plurality of arms 210 is an elongated and plate-shaped member that extends in the depthwise direction (Y axis direction) and includes a plurality of the jetting ports 211 penetrating the arm 210 in the plate thickness direction and spaced apart from one another at a given interval. The plurality of air blowers 120 blow air toward the plurality of jetting ports 211 from the rear sides of the plurality of arms 210. In Embodiment 2, the plurality of air blowers 120 are provided in one-to-one correspondence with the plurality of jetting ports 211 provided in each of the plurality of arms 210. Note that details regarding the structure of the plurality of air blowers 120 are the same as the air blower 120 according to Embodiment 1, and as such, description thereof is omitted.

The first guide 320 is a guide for sliding the support 310 in a vertical (Z axis) direction. More specifically, the first guide 320 includes a pair of columnar members that sandwich the support 310 in the widthwise (X axis) direction. The outer side of the support 310 in the X axis direction and the inner sides of the pair of first guides 320 are connected so as to be slidable in the Z axis direction.

The second guide 330 is a guide that slides the first guide 320 to which the support 310 is connected in the depthwise (Y axis) direction. More specifically, the second guide 330 is a plate, and is sandwiched in the X axis direction by lower portions of the pair of first guides 320. The outer side of the first guide 320 in the X axis direction and the outer side of the second guide 330 are connected so as to be slidable the Y axis direction.

The third guide 340 is a guide for sliding the second guide 330 to which the support 310 and the first guide 320 is connected in the

X axis direction. More specifically, the third guide 340 is an elongated member that extends in the X axis direction, and is connected to the bottom surface of second guide 330 such that the second guide 330 is slidable in the X axis direction.

The first guide 320, the second guide 330, and the third guide 340 may each include a power source, and may be configured to be able to slide in a direction in which a member connected thereto is slidable.

With the substrate transfer apparatus 2 according to Embodiment 2, the substrate floating apparatus 100 described in Embodiment 1 is applied as the plurality of arms 210 for transferring the substrate 160. As such, while the substrate 160 is floated from the plurality of arms 210, the substrate 160 can be transferred to a predetermined placement position. Therefore, since the substrate 160 and the plurality of arms 210 are not in contact when placing and removing the substrate 160 in and from a predetermined placement position, the substrate 160 can be transferred without being damaged.

Although only some exemplary embodiments of the substrate floating apparatus according to the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

### INDUSTRIAL APPLICABILITY

The present invention is applicable as, for example, a substrate floating apparatus capable of being used to transport or transfer an object to be transported such as a liquid crystal substrate by floating the object to be transported with air.

### REFERENCE SIGNS LIST

1 substrate transport apparatus
100, 100a, 100b substrate floating apparatus
110 plate
111, 211 jetting port
120, 120a, 120b air blower
121, 121b housing
122, 122b inlet
123, 123b outlet
124, 124b diaphragm
125, 125b piezoelectric element
126 filter
127, 128 check valve
129a, 129b communicating member
130 controller
140 transport roller
150 guide roller
160 substrate
210 arm
310 support
320 first guide
330 second guide
340 third guide

1. A substrate floating apparatus that floats a substrate above a placing surface by jetting air from a plurality of jetting ports, the substrate floating apparatus comprising:
a plate having a surface that is the placing surface and including the plurality of jetting ports, the plurality of jetting ports penetrating the plate in a thickness direction of the plate and spaced apart from one another at a given interval;
a plurality of air blowers that blow air toward the plurality of jetting ports from a rear side of the plate by vibrating a diaphragm; and
a controller that controls driving of the plurality of air blowers.

2. The substrate floating apparatus according to claim 1, wherein the plurality of air blowers are provided in one-to-one correspondence with the plurality of jetting ports.

3. The substrate floating apparatus according to claim 1, wherein the controller controls driving of the plurality of air blowers individually.

4. The substrate floating apparatus according to claim 1, wherein each of the plurality of air blowers comprises:
the diaphragm;
a housing that comprises an interior space in which the diaphragm is disposed, an inlet for drawing air into the interior space, and an outlet that communicates at least one of the plurality of jetting ports with the interior space; and
a drive source that vibrates the diaphragm,
wherein the drive source draws air into the interior space of the housing through the inlet and expels air from the interior space through the outlet by vibrating the diaphragm.

5. The substrate floating apparatus according to claim 4, wherein the drive source is a piezoelectric element that vibrates when applied with voltage.

6. The substrate floating apparatus according to claim 4, wherein each of the plurality of air blowers is a blower without a check valve between the inlet and the outlet of the housing.

7. The substrate floating apparatus according to claim 4, wherein each of the plurality of air blowers is a piezoelectric pump that comprises a check valve between the inlet and the outlet of the housing.

8. The substrate floating apparatus according to claim 4, wherein each of the plurality of air blowers further comprises, at the inlet of the housing, a filter for removing dust.

9. A substrate transfer apparatus for placing and removing a substrate in and from a predetermined placement position, the substrate transfer apparatus comprising:
a plurality of arms that are elongated and plate-shaped and include a plurality of jetting ports penetrating the plurality of arms in a plate thickness direction and spaced apart from one another at a given interval;
a plurality of air blowers that blow air toward the plurality of jetting ports from rear sides of the plurality of arms; and
a controller that controls driving of the plurality of air blowers.

10. A substrate transport apparatus that transports a substrate by floating the substrate from a surface of a transporting path by jetting air from a plurality of jetting ports formed in the transporting path, the substrate transport apparatus comprising:
a plate having a surface that is the surface of the transporting path and including the plurality of jetting ports, the plurality of jetting ports penetrating the plate in a thickness direction of the plate and spaced apart from one another at a given interval;
a plurality of air blowers that blow air toward the plurality of jetting ports from a rear side of the plate; and
a controller that causes, among the plurality of air blowers, an air blower corresponding to a jetting port positioned below the substrate to blow air.
